(19) United States
(12) Patent Application Publication
(10) Pub. No.: US 2013/0280896 A1
(43) Pub. Date: Oct. 24, 2013

(54) APPARATUS FOR PRODUCING POLYCRYSTALLINE SILICON AND METHOD THEREFOR

(71) Applicants: Shuichi Ohkubo, Ibaraki (JP); Masatsugu Yamaguchi, Ibaraki (JP)

(72) Inventors: Shuichi Ohkubo, Ibaraki (JP); Masatsugu Yamaguchi, Ibaraki (JP)

(73) Assignees: JNC CORPORATION, TOKYO (JP); TOHO TITANIUM CO., LTD., KANAGAWA (JP); JX NIPPON MINING & METALS CORPORATION, TOKYO (JP)

(21) Appl. No.: 13/824,383

(22) PCT Filed: Sep. 21, 2011
(86) PCT No.: PCT/JP11/71429

§ 371 Date: Mar. 18, 2013

(30) Foreign Application Priority Data
Sep. 30, 2010 (JP) 2010-221264

(51) Int. Cl. H01L 21/67; H01L 21/02

(52) U.S. Cl. CPC H01L 21/67011; H01L 21/02532
USPC 438/488; 422/129

(57) ABSTRACT

To provide an apparatus for producing polycrystalline silicon and a method therefor to allow improvement in efficiency of polycrystalline silicon production by minimizing reactor downtime and to allow polycrystalline silicon production at a relatively low cost and in a large amount in a zinc reduction process for recovering formed silicon in a solid state. In a silicon producing apparatus for producing polycrystalline silicon by reducing silicon tetrachloride with zinc, vertical reactor 1 has reactor upper body 2 and reactor lower body 3 that can be vertically detached, and reactor lower body 3 is movable in up-and-down and left-right directions.

### TECHNICAL FIELD

The present invention relates to an apparatus for producing polycrystalline silicon and a method therefor.

### BACKGROUND ART

As a typical process for producing high-purity polycrystalline silicon used as a raw material of single crystal silicon for a semiconductor, a Siemens process may be exemplified. Purity of polycrystalline silicon produced according to the Siemens process is significantly high. On the contrary, a rate of reaction is low, an electric power consumption rate in a production cost is large, and an operation of production facilities applies a batch process. Therefore, a product price becomes high, and thus the Siemens process is unsuitable as a process for producing polycrystalline silicon for a solar cell in which a low selling price is desired.

In recent years, as a process for producing polycrystalline silicon to allow production at a lower cost as compared with the Siemens process, a proposal has been made for a zinc reduction process for producing high-purity polycrystalline silicon by reducing silicon tetrachloride with a zinc metal.

Patent literature No. 1 discloses a method in which, upon individually vaporizing high-purity silicon tetrachloride and high-purity zinc to conduct a reaction in a gas atmosphere in the temperature of 900 to 1,100° C., an electrically-conductive silicon core or tantalum core is arranged in a reactor to accelerate deposition of silicon on the core, and after completion of the reaction, the reactor is opened, and a formed needle-like or flake-like silicon product is taken out from the reactor.

Moreover, Patent literature No. 2 discloses an apparatus for producing polycrystalline silicon in which a vertical reactor having a silicon chloride gas feed nozzle, a reducing agent gas feed nozzle and an exhaust gas removal pipe as arranged on an upper side is used, and a silicon chloride gas and a reducing agent gas are fed into the reactor to form polycrystalline silicon on a leading edge of the silicon chloride gas feed nozzle by a reaction between the silicon chloride gas and the reducing agent gas, and further to keep growth downward as is formed.

According to Patent literature No. 2, grown polycrystalline silicon is ordinarily in a state of being firmly fixed to a nozzle tip, although part thereof naturally drops. In the above case, after completion of the reaction, firmly fixed polycrystalline silicon is cooled and crushed by means of a cooling and crushing apparatus arranged below the reactor or arranged separately from the reactor, and then formed silicon is discharged outside a reactor system through a shutter valve or the like arranged on a bottom of the reactor or the cooling and crushing apparatus. Under the present situation, a scraping and discharging work of polycrystalline silicon requires time, the discharging work becomes dangerous and difficult, damage to a furnace is also predicted, and the work needs a long period of time.

Thus, the zinc reduction process that has been proposed so far, in which formed silicon is recovered in a solid state, applies the batch process for, after completion of the reaction, opening a lower part of the reactor, and then taking out formed silicon, and therefore causes a problem of prolonging reactor downtime, resulting in a low production efficiency and hardly reducing a production cost. Under a situation in which a demand of polycrystalline silicon for the solar cell increasingly expands presumably in the future, realization of an apparatus for mass production of polycrystalline silicon to allow production at a lower cost is awaited.

### CITATION LIST

### Patent Literature

Patent literature No. 1: JP 4200703 B.

Patent literature No. 2: JP 2007-223822 A.

### SUMMARY OF INVENTION

### Technical Problem

In view of the actual status in the past, an object of the invention is to provide an apparatus for producing polycrystalline silicon to allow improvement in efficiency of polycrystalline silicon production by minimizing reactor downtime and to allow polycrystalline silicon production at a relatively low cost and in a large amount in a zinc reduction process for recovering formed silicon in a solid state, and a method therefor.

### Solution to Problem

An apparatus for producing polycrystalline silicon according to the invention for achieving the object includes: an apparatus for producing polycrystalline silicon by reducing silicon tetrachloride with zinc, the apparatus having a reactor constituted of a reactor upper body and a reactor lower body that can be vertically separated, wherein a zinc gas feed line and a silicon tetrachloride gas feed line are connected to an upper part of the reactor upper body, an outlet of a zinc chloride-containing exhaust gas generated in a reaction is arranged at a lower part of the reactor upper body, or at an upper part of the reactor lower body, and the reactor lower body is arranged movably in up-and-down and left-right directions.

In addition, “left-right direction” herein means a direction substantially perpendicular to the up-and-down direction.

Herein, a storage container for storing the polycrystalline silicon is preferably arranged in the reactor lower body.

Moreover, according to the invention, a carriage of which a mounting surface is movable in the up-and-down direction by a lifting means is preferably arranged in the reactor lower body, and the reactor lower body is preferably arranged so as to be movable in the up-and-down and left-right directions by means of the carriage having the lifting means.

Alternatively, according to the invention, a transport mechanism that can transport the storage container in the up-and-down direction or a horizontal direction in a state of hanging the storage container preferably provided.

Moreover, according to the invention, a polycrystalline silicon recovery means for recovering polycrystalline silicon from the storage container is preferably arranged adjacently to the reactor.

Furthermore, the invention concerns a method for producing polycrystalline silicon using the apparatus for producing polycrystalline silicon according to any one of the items described above, and the method includes:
(1) a step for allowing a silicon tetrachloride gas to react with a zinc gas by using the reactor constituted by connecting the reactor upper body and the reactor lower body;
(2) a step for detaching a grown silicon body formed by the reaction from a vicinity of the silicon tetrachloride gas feed nozzle;
(3) a step for separating and lowering the reactor lower body from the reactor upper body;
(4) a step for horizontally moving the reactor lower body by a predetermined distance; and
(5) a step for recovering polycrystalline silicon-from the reactor lower body.

### Advantageous Effects of Invention

According to a silicon producing apparatus and a silicon production method of the invention, efficiency of polycrystalline silicon production can be improved by minimizing reactor downtime, and simultaneously polycrystalline silicon can be produced at a relatively low cost and in a large amount.

### BRIEF DESCRIPTION OF DRAWINGS

FIG. 1 is a schematic view showing an apparatus for producing polycrystalline silicon according to the invention.

FIG. 2 is a schematic view showing a silicon producing apparatus of the invention in association with a silicon recovery means.

FIG. 3 is a schematic view showing a silicon producing apparatus of the invention in association with a mechanism for transporting a storage container, in particular, a schematic view showing the apparatus together with a process for taking out formed silicon.

### DESCRIPTION OF EMBODIMENTS

Hereinafter, an apparatus for producing polycrystalline silicon and a method therefor by using the silicon producing apparatus according to the invention will be explained with referring to drawings.

### Reactor

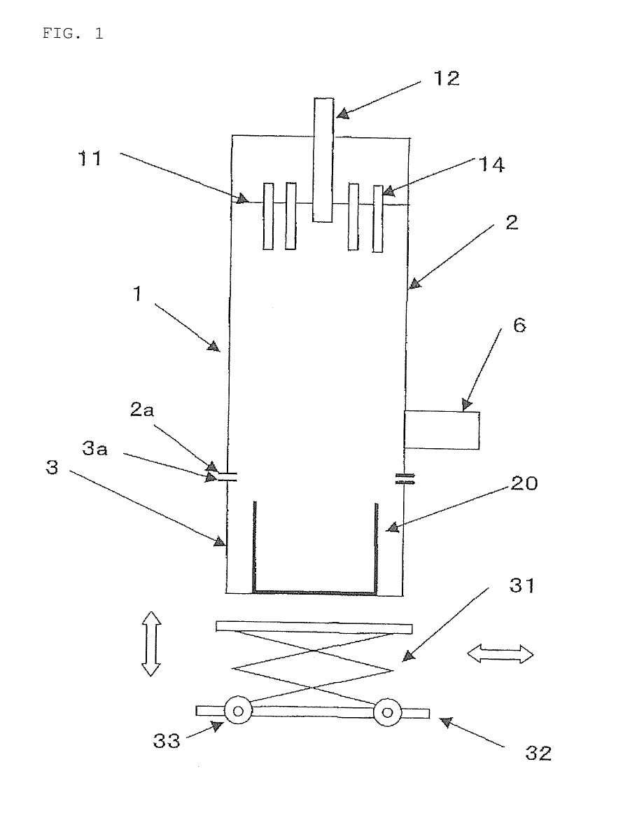

FIG. 1 is a schematic view showing an apparatus for producing polycrystalline silicon according to one Example of the invention.

In the apparatus for producing polycrystalline silicon according to the present Example, substantially cylindrically-shaped vertical reactor 1 is adopted between a second floor and a third floor, for example. The vertical reactor 1 is constituted of two divided bodies including reactor upper body 2 and reactor lower body 3, and reactor upper body 2 is fixed to a frame, and simultaneously reactor lower body 3 is arranged movably when reactor lower body 3 is separated from reactor upper body 2. Moreover, reactor upper body 2 and reactor lower body 3 are vertically connected through a heat-resistant sealant in order to maintain air tightness.

On the other hand, carriage 32 having lifting means 31 is arranged on a lower surface of reactor lower body 3. Then, reactor lower body 3 is arranged, when reactor lower body 3 is separated from reactor upper body 2, to be movable in an up-and-down direction by lifting means 31, and simultaneously movable in a horizontal direction by carriage 32.

In a silicon producing apparatus having such vertical reactor 1, an operation of inserting and exchanging the heat-resistant sealants can be easily performed by starting lifting means 31 to vertically move reactor lower body 3 during connection between reactor upper body 2 and reactor lower body 3, or during separation of reactor upper body 2 from reactor lower body 3.

In connection between reactor upper body 2 and reactor lower body 3, air tightness can be surely maintained, if connecting flanges 2a and 3a are arranged in reactor upper body 2 and reactor lower body 3, respectively, a plurality of bolts (not shown) are inserted through the connecting flanges 2a and 3a and the connecting flanges are fastened with each other using the bolts.

Furthermore, a heating means (not shown) is provided outside the reactor upper body 2.

At an upper part of reactor upper body 2 of vertical reactor 1, top plate 11 is attached integrally with an inner wall of reactor upper body 2. Moreover, zinc gas feed nozzle 12 is attached through a substantially central part of the top plate 11, and simultaneously a plurality of silicon tetrachloride gas feed nozzles 14 are attached in the form of surrounding the nozzle 12. Moreover, zinc gas feed nozzle 12 and silicon tetrachloride gas feed nozzle 14 are connected through each feed line to a zinc evaporator (not shown) and a silicon tetrachloride gas evaporator (not shown) respectively arranged outside the vertical reactor 1.

A material constituting reactor upper body 2 is not particularly limited, if the material has durability in an operating temperature range of 800 to 1,200° C. at which a reaction between a silicon tetrachloride gas and a zinc gas is performed. Specific examples include quartz, silicon carbide and silicon nitride. Moreover, specific examples of an inner wall shape of reactor upper body 2 and reactor lower body 3 include a cylindrical shape, a rectangular parallelepiped shape, a polygon shape or a shape formed by partially combining the shapes, but the shape is not particularly limited thereto.

Moreover, outlet 6 for discharging gases such as the zinc chloride gas generated during a reduction reaction, an unreacted zinc gas and an unreacted silicon tetrachloride gas is arranged at a lower part of reactor upper body 2.

Outlet 6 is connected through a connection line with a zinc chloride condenser (not shown) arranged adjacently to the lower part of reactor upper body 2, a by-product zinc chloride gas and the unreacted zinc gas discharged from outlet 6 are separated mainly into an unreacted gas mainly containing silicon tetrachloride and a condensed liquid by means of the zinc chloride condenser maintained at a predetermined temperature, and a melt held at a liquid state is separated into two layers including a zinc chloride melt and a zinc melt by difference in specific gravity. The zinc chloride melt is further sent to an electrolytic process, and is separated into chlorine and zinc by electrolysis. Zinc is reused as a reducing agent for a zinc reduction reaction, and chlorine is used as a chlorinating agent of a silicon metal for producing silicon tetrachloride, and thus can also be reused as a raw material of the zinc reduction reaction. Thus, an integrated system for producing polycrystalline silicon is constituted in which high-purity polycrystalline silicon is produced, and simultaneously the by-product is repeatedly reused.

On the other hand, vertical reactor 1 constituted by connecting reactor upper body 2 and reactor lower body 3 is arranged by being fixed to a floor frame with a suitable means while the reduction reaction is performed. An upper part of reactor lower body 3 is open, and when reactor lower body 3 is connected to reactor upper body 2 through the heat-resistant sealant, an inner space of reactor lower body 3 is united with an inner space of reactor upper body 2 to form a vertically long reaction space. A heating means (not shown) is provided inside the reactor lower body 3.

Specific examples of shapes of reactor lower body 3 include a cylindrical shape, a rectangular parallelepiped shape, a polygon shape, or a shape formed by partially combining the shapes, each having a side wall, but the shape is not particularly limited thereto. Moreover, reactor lower body 3 can also take shape including a disc shape, a truncated cone shape and a truncated pyramid shape, each without a side wall.

Reactor lower body 3 can be constituted by arranging a heat-insulating refractory inside a metal shell, and further forming in an inside thereof a lining layer of a material including an unshaped refractory or quartz, silicon carbide, silicon nitride or the like. However, a constitution of reactor lower body 3 is in no way limited to Examples. A material of reactor lower body 3 can be freely selected, if the material thereof is tough enough to withstand an unexpected dropping impact of grown silicon body 22 formed in a vicinity of silicon tetrachloride gas feed nozzle 14 of reactor upper body 2, and is heat resistant without reacting with a reactant gas and a formed gas.

At a lower part of reactor lower body 3, carriage 32 having a plurality of wheels 33 is arranged. The carriage 32 is movable on a rail arranged on a floor in a left-right direction (horizontal direction) in the drawing.

In addition, an example is explained as described above in which outlet 6 for discharging the zinc chloride gas generated during the reduction reaction, and the unreacted gas such as the zinc gas and the silicon tetrachloride gas is arranged at the lower part of reactor upper body 2, but the invention is not limited thereto. A case where outlet 6 for discharging the unreacted gas is arranged to reactor lower body 3 is also one embodiment of the invention. In the above case, a line for connecting outlet 6 and the zinc chloride condenser can be separated on the midway.

Arrangement of outlet 6 to either reactor lower body 3 or reactor upper body 2 is determined depending on arrangement conditions in a plant as a whole including the zinc chloride condenser arranged on a side downstream of the reactor, plant operational conditions or the like.

In vertical reactor 1, the reaction between silicon tetrachloride and zinc is performed in the temperature range of 800 to 1,200° C. The reaction is further preferably performed in the temperature range of 900° C. in a vicinity of a boiling point of zinc to 1,100° C. When the temperature increases to 1,100° C. or higher, a reverse reaction increases and an impurity concentration in formed silicon increases.

### Mechanism for Recovering Polycrystalline Silicon

In the apparatus for producing polycrystalline silicon, a recovery mechanism for recovering formed silicon is provided.

Hereinafter, the recovery mechanism for recovering silicon formed in vertical reactor 1 will be explained.

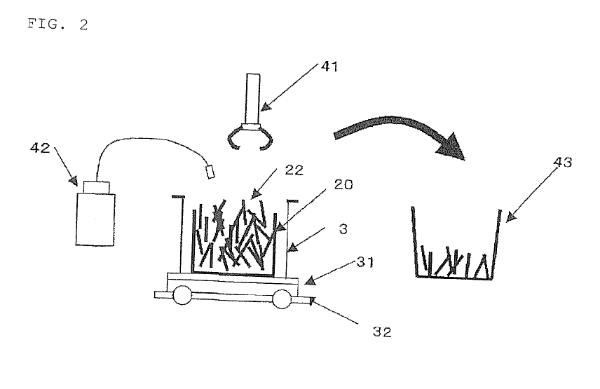

For example, as shown in FIG. 2, the recovery mechanism for recovering formed silicon is constituted of storage container 20 for storing formed silicon, carriage 32 having lifting means 31, first polycrystalline silicon recovery means 41 having a gripping tool as arranged adjacently to vertical reactor 1, second polycrystalline silicon recovery means 42 by a vacuum sucker, and so forth. Lifting means 31 is preferably constituted of a cylinder mechanism or a bellows mechanism.

After completion of the reaction, the grown silicon body formed in the vicinity of silicon tetrachloride gas feed nozzle 14 by the reduction reaction between silicon tetrachloride and zinc is detached from silicon tetrachloride gas feed nozzle 14 by a mechanical means (not shown) introduced into reactor 1, and collected into storage container 20 provided in reactor lower body 3. Then, an arm of lifting means 31 located at the lower part of reactor lower body 3 is extended upward, and a head of lifting means 31 is brought in contact with a bottom of reactor lower body 3 to support reactor lower body 3.

When the bottom of reactor lower body 3 is supported, the bolts between flanges 2a and 3a connecting reactor upper body 2 and reactor lower body 3 are removed, and a fixed part of reactor lower body 3 that is arranged by being fixed to the floor frame by a suitable means is unfastened.

Subsequently, reactor lower body 3 is lowered by lifting means 31, and reactor upper body 2 and reactor lower body 3 are separated. Then, carriage 32 having lifting means 31 that carries storage container 20 storing the grown silicon body horizontally moves on a rail (not shown) to a predetermined position. The grown silicon body in storage container 20 is sequentially taken out from storage container 20 by first polycrystalline silicon recovery means 41 provided with the gripping tool, and collected into recovery container 43. Every portion of granular and powdery silicon remaining in storage container 20 is recovered by second polycrystalline silicon recovery means 42, such as the vacuum sucker.

As a material of an inner surface of storage container 20, the material that does not react with silicon, such as quartz, silicon carbide and silicon nitride, is preferably used. Above all, quartz is particularly preferred. Storage container 20 may be arranged in close contact with an inner wall of a side wall of reactor lower body 3, or may be arranged with a gap between storage container 20 and the inner wall of the side wall of reactor lower body 3.

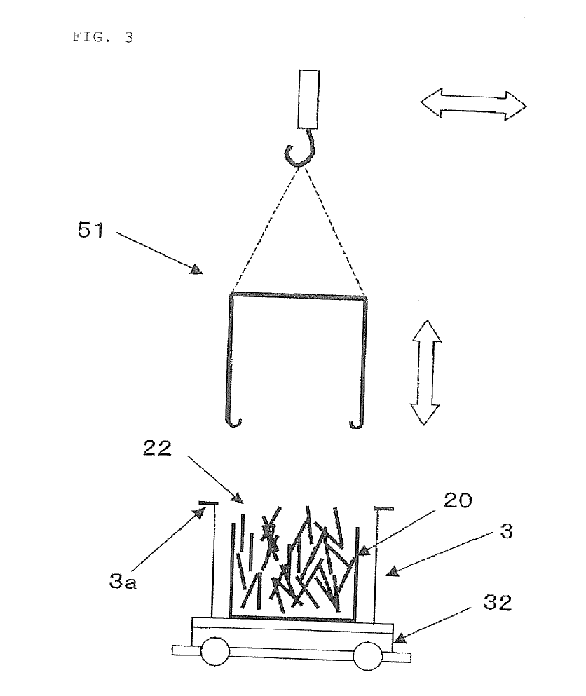

Moreover, as shown in FIG. 3, formed silicon can be recovered by arranging storage container transport mechanism 51 for hanging and transporting storage container 20, and then moving storage container 20 to any other place by storage container transport mechanism 51.

As a polycrystalline silicon recovery means when the storage container 20 is moved to any other place by using hanging storage container transport mechanism 51, formed silicon may be taken out by reversing storage container 20, or first polycrystalline silicon recovery means having the gripping tool as shown in FIG. 2 or second recovery means 42 by the vacuum sucker or the like may be adopted.

Storage container 20 is preferably hung by fastening a hook of transport mechanism 51 to a plurality of handles attached to an outer wall of the storage container or a supporting bar attached to a bottom of the storage container.

In the explanation above, an example of performing the reduction reaction while leaving storage container 20 in reactor lower body 3 is explained, but an embodiment is allowed in which the reaction is performed without having storage container 20 in reactor lower body 3. The grown silicon body in the above case is recovered according to procedures as described below.

More specifically, after completion of the reduction reaction, reactor lower body 3 is separated from reactor upper body 2 by lifting means 31 provided to carriage 32, separated reactor lower body 3 is lowered by a predetermined distance and moved in a horizontal direction by a predetermined distance. Subsequently, an empty storage container is brought under reactor upper body 2 by a different lifting means with a carriage, and the empty storage container is fixed and arranged on a previous position of reactor lower body 3. Then, grown silicon body 22 formed in the vicinity of silicon tetrachloride gas feed nozzle 14 is detached by a mechanical means (not shown) that is introduced into the reactor, and collected into storage container 20.

Subsequent operations are performed in a similar procedures explained above.

### EXAMPLES

Hereinafter, a method for producing high-purity polycrystalline silicon by using the apparatus for producing polycrystalline silicon as described above is explained below, but the invention is in no way limited to Examples.

### Example 1

(1) One zinc gas feed nozzle 12 having an inner diameter of 120 mm was arranged in a center of top plate 11 of vertical reactor 1 having an inner diameter of 900 mm, and twenty silicon tetrachloride gas feed nozzles 14 each having an inner diameter of 30 mm were arranged to surround gas feed nozzle 12 at an equal interval with each other.

(2) Into vertical reactor 1 constituted of reactor upper body 2 and reactor lower body 3, a silicon tetrachloride gas heated to 1,100° C. was fed at a feed rate of 150 kg/Hr, and a zinc gas heated to 950° C. was fed at a feed rate of 100 kg/Hr, and a reaction was performed.

(3) The reaction was terminated after 7 hours from starting the reaction. Then, a decrease in an internal temperature was started by blowing a nitrogen gas into vertical reactor 1.

(4) A decrease in an overall temperature in vertical reactor 1 to about 500° C. was confirmed, and in order to recover a grown silicon body grown in a vicinity of silicon tetrachloride gas feed nozzle 14 of reactor upper body 2, a rammer (not shown) was inserted into the reactor and swung in all directions, and thus the grown silicon body formed in the vicinity of silicon tetrachloride gas feed nozzle 14 was detached and collected into storage container 20 arranged in reactor lower body 3.

(5) An arm of lifting means 31 located at a lower part of reactor lower body 3 was extended upward, and a head of lifting means 31 was brought into contact with a bottom of reactor lower body 3 to support reactor lower body 3. Subsequently, bolts of flanges connecting reactor upper body 2 and reactor lower body 3 were removed, and a fixed part fixing reactor lower body 3 to a floor frame was unfastened.

Subsequently, reactor lower body 3 was lowered by lifting means 31 to separate reactor upper body 2 and reactor lower body 3, and then horizontally moved to a predetermined position by carriage 32. The grown silicon body in storage container 20 was sequentially taken out from storage container 20 by polycrystalline silicon recovery means 41 having a gripping tool, and collected into recovery container 43. Every portion of needle-like, granular or powdery silicon product remaining in storage container 20 was recovered by a vacuum sucker being silicon recovery means 42. A total of 70 kg of polycrystalline silicon was recovered.

### REFERENCE SIGNS LIST

1 Vertical reactor

2 Reactor upper body

3 Reactor lower body

6 Outlet

11 Top plate

12 Zinc gas feed nozzle

14 Silicon tetrachloride gas feed nozzle

20 Storage container

22 Grown silicon body

31 Lifting means

32 Carriage

41 First polycrystalline silicon recovery means

42 Second polycrystalline silicon recovery means

43 Recovery container

51 Storage container transport mechanism

1. An apparatus for producing polycrystalline silicon by reducing silicon tetrachloride with zinc, the apparatus comprising a reactor constituted of a reactor upper body and a reactor lower body that can be vertically separated, wherein a zinc gas feed line and a silicon tetrachloride gas feed line are connected to an upper part of the reactor upper body, an outlet of a zinc chloride-containing exhaust gas generated in a reaction is arranged at a lower part of the reactor upper body, or at an upper part of the reactor lower body, and the reactor lower body is arranged movably in up-and-down and left-right directions.

2. The apparatus for producing polycrystalline silicon according to claim 1, comprising a storage container for storing the polycrystalline silicon in the reactor lower body.

3. The apparatus for producing polycrystalline silicon according to claim 1, wherein a carriage of which a mounting surface is movable in an up-and-down direction by a lifting means is arranged in the reactor lower body, and the reactor lower body is arranged to be movable in up-and-down and left-right directions by the carriage having the lifting means.

4. The apparatus for producing polycrystalline silicon according to claim 2, comprising a transport mechanism that can transport the storage container in an up-and-down direction or a horizontal direction in a state in which the storage container is hung.

5. The apparatus for producing polycrystalline silicon according to claim 2, wherein a polycrystalline silicon recovery means for recovering polycrystalline silicon from the storage container is arranged adjacently to the reactor.

6. A method for producing polycrystalline silicon using the apparatus for producing polycrystalline silicon according to claim 1, the method comprising:
(1) a step for allowing a silicon tetrachloride gas to react with a zinc gas by using the reactor constituted by connecting the reactor upper body and the reactor lower body;
(2) a step for detaching a grown silicon body formed by the reaction from a vicinity of the silicon tetrachloride gas feed line;
(3) a step for separating and lowering the reactor lower body from the reactor upper body;
(4) a step for horizontally moving the reactor lower body by a predetermined distance; and
(5) a step for recovering polycrystalline silicon from the reactor lower body.
